(19) United States
(12) Patent Application Publication
(10) Pub. No.: US 2011/0192626 A1
(43) Pub. Date: Aug. 11, 2011

(54) APPARATUS WITH CASE

(75) Inventors: YUN-LUNG CHEN, Tu-Cheng (TW); GANG SU, Shenzhen City (CN); ZHONG-HAI ZHANG, Shenzhen City (CN)

(73) Assignees: HONG FU JIN PRECISION INDUSTRY (ShenZhen) CO.LTD., Shenzhen City (CN); HON HAI PRECISION INDUSTRY CO., LTD., Tu-Cheng (TW)

(21) Appl. No.: 12/884,685

(22) Filed: Sep. 17, 2010

(30) Foreign Application Priority Data
Feb. 9, 2010 (CN) 201020302734.2

(51) Int. Cl. H05K 5/00

(52) U.S. Cl. 174/50

(57) ABSTRACT

An apparatus includes a case. The case includes a bottom and two opposite sidewalls located on the bottom. A wall flange is located on each sidewall. The wall flange includes a supporting portion for supporting a cover and an extending portion extending down from the supporting portion. A plurality of through openings is defined in the wall flange, and a plurality of resilient pieces is located on the wall flange, for electrically connecting with the cover. Each through opening extends from the extending portion to the supporting portion.

### BACKGROUND

1. Technical Field

The present disclosure relates to an apparatus with a case, which has improved electronic magnetic interference (EMI)-resistant capability.

2. Description of Related Art

EMI exists in many electronic devices, such as computer systems. Therefore, an electronic device enclosure should be designed to reduce EMI from harming users, so there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an apparatus in accordance with an embodiment.

FIG. 2 is an enlarged view of portion II of FIG. 1.

FIG. 3 is an isometric view of an apparatus in accordance with prior art.

FIG. 4 is an enlarged view of portion IV of FIG. 3.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

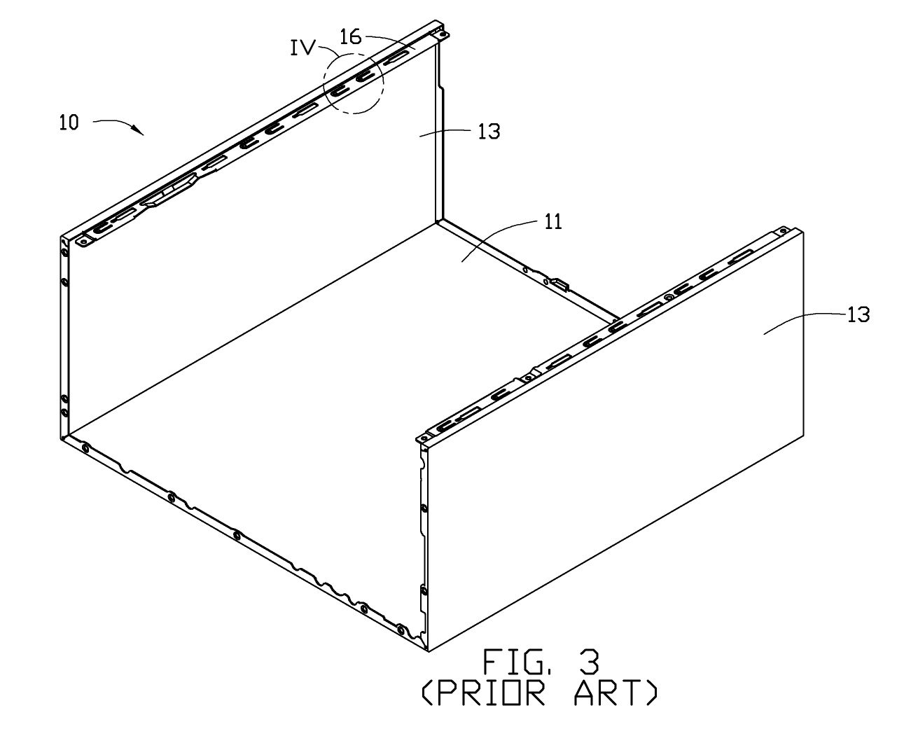

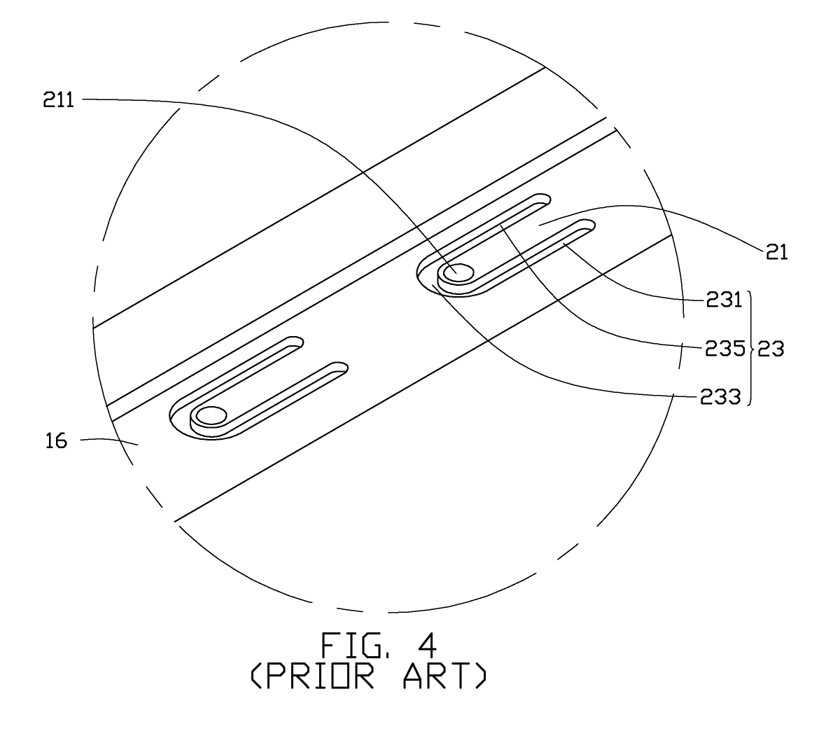

Referring to FIGS. 3-4, a conventional apparatus, according to the prior art, includes a chassis 10. The chassis 10 includes a bottom plate 11 and two opposite side plates 13. The side plates 13 are substantially parallel to each other and perpendicular to the bottom plate 11. A supporting flange 16 extends in from a top edge of each side plate 13. The supporting flange 16 is perpendicular to each side plate 13. A plurality of through holes 23 is defined in each supporting flange 16 by a punch process and extends in a direction parallel to the side plates 13. Each through hole 23 includes a first straight portion 231, an arc portion 233 and a second straight portion 235. The arc portion 233 communicates with the first and second straight portions 231, 235. A finger piece 21 is thereby formed in each through hole 23. The finger pieces 21 extend in a direction parallel to the side plates 13. A protrusion 211 is located on a top surface of each finger piece 21 at a distal end. The protrusions 211 can contact electrically with a cover (not shown), which is secured to the side plates 13 to cover the chassis 10, for reducing EMI from harming users. However, the finger pieces 21 are easily decrease EMI-resistant capability when they experience permanent deformation due to cyclical fatigue.

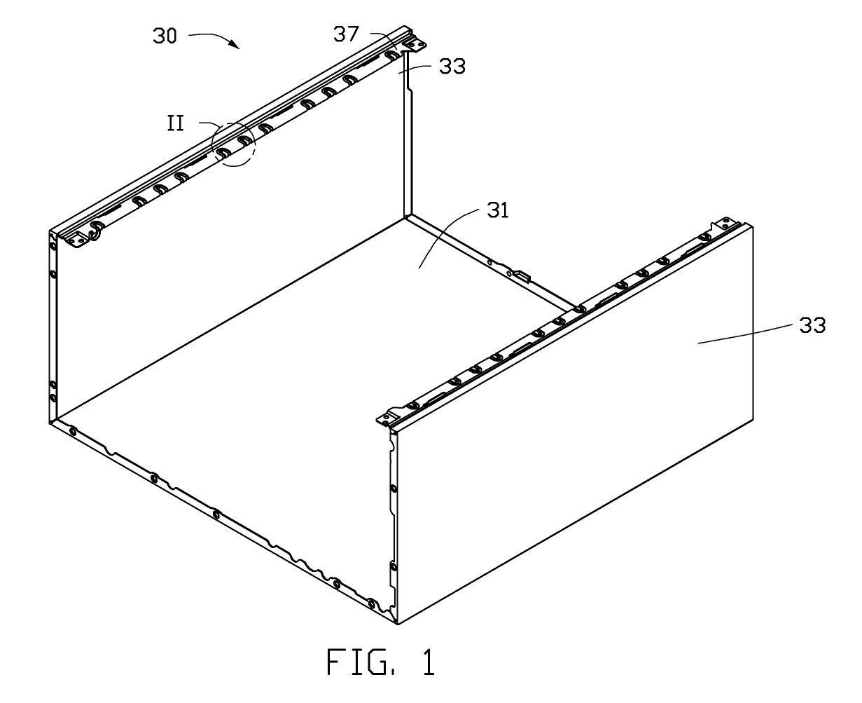

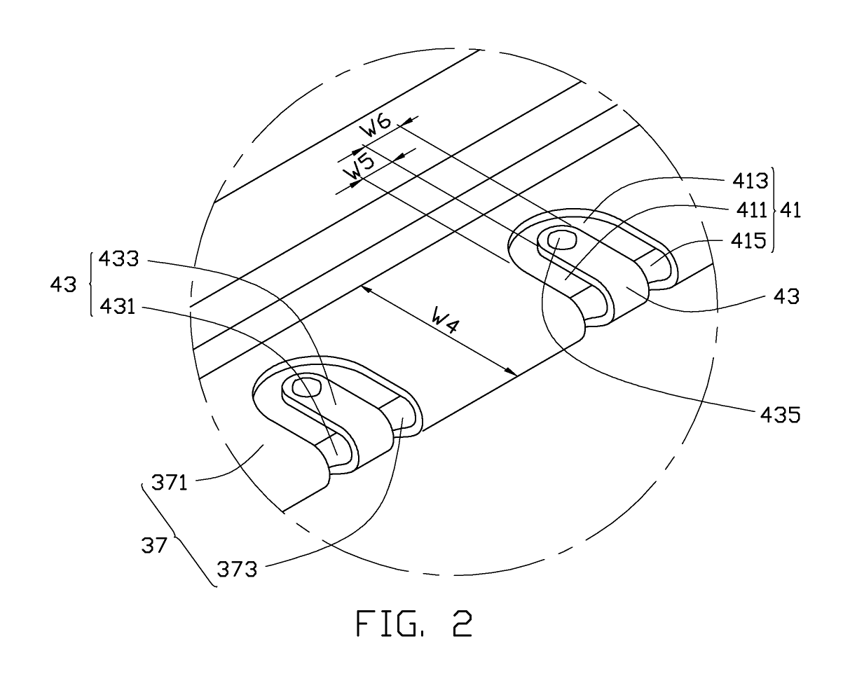

An improved apparatus is provided. Referring to FIGS. 1-2, the apparatus, in accordance with an embodiment, includes a case 30. The case 30 includes a bottom 31 and two opposite sidewalls 33 located on the bottom 31. In an embodiment, the sidewalls 33 are substantially parallel to each other and perpendicular to the bottom 31. A wall flange 37 extends in from a top edge of each sidewall 33. In an embodiment, the wall flange 37 is substantially perpendicular to each sidewall 33. The wall flange 37 includes a supporting portion 371 connected to the corresponding sidewall 33 and an extending portion 373 extending down from the supporting portion 371. A plurality of through openings 41 is defined in the supporting portion 371 and the extending portion 373, and the part of each through opening 41 in the supporting portion 371 extends in a direction substantially perpendicular to the sidewalls 33. Each through opening 41 includes a first portion 411, a connecting portion 413 and a second portion 415. Each of the first and second portions 411, 415 are located in the supporting portion 371 and the extending portion 373, and the connecting portion 413 is located in the supporting portion 371. The connecting portion 413 communicates with the first and second portions 411, 415. A plurality of resilient pieces 43 is located on the wall flange 37 and connected to the extending portion 373. Each resilient piece 43 is surrounded by each through opening 41 and includes a first resilient portion 431, and a second resilient portion 433. The first resilient portion 431 is connected to the extending portion 373, and the second resilient portion 433 extends up from the first resilient portion 431. The second resilient portion 433 of each resilient piece extends in a direction substantially perpendicular to the sidewalls 33 and is capable of being connected to a cover (not shown), which is secured to the sidewall 33 to cover the case 30, for reducing EMI from harming users. In an embodiment, a point 435 is located on a top surface of each resilient piece 43 at a distal end, which is substantially adjacent the corresponding sidewall 33, and the points 435 can be electrically connected to the cover.

Because the wall flange 37 includes the supporting portion 371 and the extending portion 373, the wall flange 37 can be reinforced. So the wall flange 37 can be made of a relatively thin gauge metal, such as a 0.4 mm metal plate, and still be strong enough to secure a cover to the case 30. Furthermore, the through openings 41 extend in a direction substantially perpendicular to the sidewalls 33, so the through openings 41 and the resilient pieces 43 have sufficient enough width, which is not limited by the width of the supporting portion 371 or the wall flange 37. For example, the width W4 of the supporting portion 371 is not less than 9 mm, but not greater than 11 mm, the width W5 of each through opening 41 can be not less than 2 mm, but not greater than 3 mm, the width W6 of each resilient piece 43 can be not less than 3 mm, but not greater than 4 mm. In one embodiment, the width W5 of each through opening 41 is 2.5 mm, and the width W6 of each resilient piece 43 is 3.5 mm. Therefore, a die, that has the same size width W5 of the through opening 41 and is used to punch the through openings 41, can be strong enough not to be easily damaged in the punching process. In addition, the resilient pieces 43 can be also reinforced to improve long term EMI-resistant capability.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An apparatus comprising:
a case, the case comprising a bottom and two opposite sidewalls located on the bottom; a wall flange located on each sidewall; the wall flange comprising a supporting portion, for supporting a cover, and an extending portion, extending down from the supporting portion; the wall flange defining a plurality of through openings and comprising a plurality of resilient pieces for electrically connecting with the cover; each of the plurality of the resilient pieces are surrounded by each of the plurality of through openings; and each of the plurality of through openings extends from the extending portion to the supporting portion.

2. The apparatus of claim 1, wherein each of the plurality of through openings comprises a first portion, a connecting portion, and a second portion; and the connecting portion communicates with the first and second portions.

3. The apparatus of claim 1, wherein a width of each of the plurality of through openings is less than 3 mm, but greater than 2 mm.

4. The apparatus of claim 3, wherein a width of each of the plurality of through openings is about 2.5 mm.

5. The apparatus of claim 1, wherein a width of each of the plurality of resilient pieces is less than 4 mm, but greater than 3 mm.

6. The apparatus of claim 5, wherein a width of each of the plurality of resilient pieces is about 3.5 mm.

7. The apparatus of claim 1, wherein each of the plurality of resilient pieces comprises a first resilient portion, connected to the extending portion, and a second resilient portion, extending from the extending portion; and the second resilient portion is in a part of the corresponding through opening defined in the supporting portion.

8. The apparatus of claim 7, wherein a point is located on the second resilient portion of each of the plurality of resilient pieces for electrically connecting with the cover.

9. The apparatus of claim 7, wherein the second resilient portion of each of the plurality of resilient pieces is substantially perpendicular to the sidewalls.

10. The apparatus of claim 7, wherein a first angle is defined between the first and second resilient portions of each of the plurality of resilient pieces, and the first angle is greater than zero degrees, but less than 90 degrees.

11. The apparatus of claim 1, wherein a part of each of the plurality of through openings in the supporting portion is substantially perpendicular to the sidewalls.

12. The apparatus of claim 1, wherein a second angle is defined between the supporting portion and the extending portion, and the second angle is greater than zero degrees, but less than 90 degrees.

13. An apparatus comprising:
a case, a wall flange located on the case; the wall flange comprising a supporting portion, for supporting a cover, and an extending portion, extending down from the supporting portion; the wall flange defining a plurality of through openings and comprising a plurality of resilient piece; each of the plurality of through openings extends from the extending portion to the supporting portion; the plurality of resilient pieces extend from the wall flange; each of the plurality of resilient pieces is adjacent one of the plurality of through openings; each of the plurality of resilient pieces comprises a first resilient portion, connected to the extending portion, for electrically connecting with the cover, and a second resilient portion extending from the first resilient portion; and a first angle is defined between the first and second resilient portions of each of the plurality of resilient piece, and the first angle is greater than zero degrees, but less than 90 degrees.

14. The apparatus of claim 13, wherein each of the plurality of through openings comprises a first portion, a connecting portion, and a second portion; and the connecting portion communicates with the first and second portions.

15. The apparatus of claim 13, wherein the case comprises a bottom and a sidewall located on the bottom; and the wall flange is located on the sidewall.

16. The apparatus of claim 15, wherein each of the plurality of resilient pieces comprises a first resilient portion, connected to the extending portion, and a second resilient portion, extending from the extending portion; and the second resilient portion is in a part of the corresponding through opening defined in the supporting portion.

17. The apparatus of claim 16, wherein the second resilient portion of each of the plurality of resilient pieces is substantially perpendicular to the sidewalls.

18. The apparatus of claim 15, wherein a part of each of the plurality of through openings in the supporting portion is substantially perpendicular to the sidewalls.

19. The apparatus of claim 13, wherein a second angle is defined between the supporting portion and the extending portion, and the second angle is greater than zero degrees, but less than 90 degrees.

20. The apparatus of claim 13, wherein a width of each of the plurality of through openings is less than 3 mm, but greater than 2 mm; and a width of each of the plurality of resilient pieces is less than 4 mm, but greater than 3 mm.
